(19) United States
(12) Patent Application Publication
(10) Pub. No.: US 2025/0118348 A1
(43) Pub. Date: Apr. 10, 2025

(54) CRITICAL TIMING DRIVEN DYNAMIC VOLTAGE FREQUENCY SCALING BASED ON AN AT-SPEED SCAN

(71) Applicant: Micron Technology, Inc., Boise, ID (US)

(72) Inventor: Leon Zlotnik, Camino, CA (US)

(21) Appl. No.: 18/787,824

(22) Filed: Jul. 29, 2024

Related U.S. Application Data
(60) Provisional application No. 63/587,871, filed on Oct. 4, 2023.

(51) Int. Cl. G11C 7/22; G11C 7/10

(52) U.S. Cl. CPC G11C 7/222; G11C 7/1069

(57) ABSTRACT

An example method can include performing a first sensing operation associated with circuitry on a system on chip (SoC) to determine a first data value, performing a second sensing operation associated with circuitry of a sensor the SoC to determine a second data value, responsive to the first data value and the second data value being the same data value, determining that a clock margin is sufficient, and responsive to the first data value and the second data value being different data values, determining that a clock margin is insufficient. In some examples, a voltage-frequency operating combination associated with at least one operation of the SoC can be adjusted to a particular stored voltage-frequency operating combination that provides a sufficient clocking margin.

### PRIORITY INFORMATION

This application claims the benefit of U.S. Provisional Application No. 63/587,871, filed on Oct. 4, 2023, the contents of which are incorporated herein by reference.

### TECHNICAL FIELD

Embodiments of the disclosure relate generally to critical timing driven dynamic voltage frequency scaling (DVFS) based on an at-speed scan.

### BACKGROUND

Various types of electronic devices such as digital logic circuits and memory systems may store and process data. A digital logic circuit is an electronic circuit that processes digital signals or binary information, which can take on two possible values (usually represented as 0 and 1). The digital logic circuit can use logic gates to manipulate and transform the digital signals or binary information. Digital logic circuits can be, for example, used in a wide range of electronic devices including computers, calculators, digital clocks, and many other electronic devices that employ digital processing. Digital logic circuits can be designed to perform specific logical operations on digital inputs to generate digital outputs, and, in some instances, can be combined to form more complex circuits to perform more complex operations. In general, the power supply, voltage control, and/or clock control can change a voltage or frequency during operation of the digital logic. A memory device can include one or more memory devices that store data. The memory devices can be, for example, non-volatile memory devices and volatile memory devices. In general, a host system can utilize a memory system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1 illustrates an example system for critical timing driven dynamic voltage frequency scaling (DVFS) based on an at-speed scan in accordance with some embodiments of the present disclosure.

FIGS. 2A-2B each illustrate an example system for critical timing driven dynamic voltage frequency scaling (DVFS) based on an at-speed scan in accordance with some embodiments of the present disclosure.

FIGS. 3A-3B each illustrate an example system for critical timing driven dynamic voltage frequency scaling (DVFS) based on an at-speed scan including a sensor in accordance with some embodiments of the present disclosure.

FIG. 4 illustrates an example method for critical timing driven dynamic voltage frequency scaling (DVFS) based on an at-speed scan in accordance with some embodiments of the present disclosure.

### DETAILED DESCRIPTION

Aspects of the present disclosure are directed to critical timing driven dynamic voltage frequency scaling (DVFS) based on an at-speed scan. As will be described below, a sensor can monitor critical timing of a circuit. The sensor can include a flip-flop such as an individual flip-flop. The sensor can be included in a scan chain, as described herein. The sensor can be configured to operate with different timing such as being configured to operate at a different frequency/phase, for instance, due to increased clock frequency and/or a reduced voltage which varies the arrival timing of data as compared to arrival timing of the data in data storage elements, e.g., flip-flops of a system on chip (SoC) at a functional critical endpoint where the data is sampled. In this way, the voltage and/or clock frequency can be adjusted to provide a sufficient margin and thereby avoid any issues (e.g., data errors) that otherwise are associated with operation with an insufficient margin. For instance, a particular voltage-frequency operating combination that is suitable (e.g., provides a sufficient margin) can be selected from a plurality of stored voltage-frequency operating combinations, as described herein. Yet, the approaches herein, at least due to selection of the particular voltage-frequency operating combination that is suitable for a given condition (e.g., a particular operating temperature, particular age, etc.) can also reduce an operational voltage of the SoC and/or increase an operational frequency of the SoC to yield improved SoC performance (e.g., reduce power consumption of the SoC and/or a reduce latency associated with operation of the SoC, etc.).

The voltage-frequency operating combinations that are suitable at a given operating condition such as an operating temperature, operational age (e.g., based on a duration of operation, quantity of cycles, etc.) can be determined via the sensor by incrementally altering (e.g., reducing or increasing) a voltage and/or incrementally altering (e.g., reducing or increasing) a clock frequency until a timing violation is detected by the sensor or the absence of a timing violation is detected by the sensor. For instance, the voltage can be incrementally reduced and/or a clock frequency can be incrementally increased until a timing violation is detected by the sensor. Similarly, the voltage can be incrementally increased and/or the clock frequency can be incrementally reduced until a timing violation is not detected by the sensor. Thus, the approaches herein can determine the presence or absence of timing violations to permit the subsequent determination of at least one voltage-frequency operating combination, such as those described herein, that results in a sufficient margin (e.g., does not result in an insufficient margin). For instance, several voltage-frequency operating combinations may be stored in a data structure and thereby permit the circuit to be configured to a given voltage frequency operating combination to ensure that the circuit operates with a sufficient or optimal margin across a variety of potential operating conditions such as operating temperatures, as described herein. Yet, the approaches herein at least due to the incremental variation in frequency and/or voltage may not be prone to overshooting the optimal margin. Therefore, unlike other approaches the approaches herein can employ sensors with fewer components (e.g., an individual flip-flop as compared a plurality of flip-flops in a sensor), may yield a reduction in computational overhead, and may yield a reduction in any latency associated with voltage-frequency scaling to operate a circuit with an optimal margin. In one example, a voltage and/or a clocking frequency of at least one operation of the SoC can be adjusted, for instance, to a particular voltage-frequency operating combination stored in a data structure that corresponds to an operating condition such as an operating temperature of the SoC. in response to determining that the clock margin is insufficient). Consequently, the approaches herein can improve the performance of the circuit and/or devices employ the circuit operating at the optimal margin. For instance, the approaches herein can permit circuit testing and subsequent Dynamic voltage and frequency scaling (DVFS) to address logic 0-to-1 transition delay (slow-to-rise fault) or logic 1-to-0 transition delay (slow-to-fall fault), etc.

Voltage and frequency scaling (VFS) can be used to match system power consumption with desired performance. Workloads associated with a system (e.g., a computing system) can be monitored to determine a setting for voltage and clock speed and can configure the hardware of the system appropriately. DVFS is a technique that aims at reducing the power consumption of a system or boosting the system performance by dynamically adjusting voltage and frequency of the system. This can exploit the fact that the system generally has a discrete frequency and voltage setting. Dynamic voltage scaling to increase voltage can be referred to as overvolting, whereas dynamic voltage scaling to decrease voltage can be referred to as undervolting. Undervolting can be performed in order to conserve power, particularly in laptops and other mobile devices, where energy comes from a battery and thus is limited, or, in rare cases, to increase reliability. Overvolting can be performed in order to support higher frequencies for performance. The term “overvolting” may also be used to refer to increasing static operating voltage of components to allow operation at higher speed (e.g., while overclocking).

The voltage and frequency applied to various components of the systems described herein can be dynamically adjusted based on the desired power and performance associated with the voltage, frequency, and/or temperature data (in addition to other parameters, if monitored) that is gathered during monitoring operations (e.g., an AC (or at-speed) scan operation, or other data gathering and/or monitoring operations), and/or by a dedicated, embedded monitor, a built-in self test (BIST), or some table compiled using modeling and/or characterization, among other approaches. The voltage, frequency, and/or temperature data of the monitoring operations (e.g., AC scans or other monitoring operations) can gather real-measured data for a large portion of the system and provide a more accurate approach to adjusting the voltage and frequency for scaling. As an example, real-measured data can refer to data that is not from simulation and is from an actual scan and not extrapolated. Accordingly, voltage frequency scaling can provide benefits in systems (e.g., application-specific integrated circuits (ASICs), field-programmable gate arrays (FPGAs), automated power management systems, etc.) that rely on instantaneous (or near-instantaneous) changes to the voltage, frequency, and temperature of the system where each parameter may affect one of the other parameters.

In some previous approaches, a clock frequency or period using an excessive margin (e.g., excessive clock margin) can be used in order to avoid incorrect data being sampled from a location in an SoC. As used herein, an excessive clock margin refers to a slower clock or a clock with a longer period. As an example, if the clock period is long enough to cover the propagation time of the data from a start point (e.g., rising edge of a clock) to an end point (e.g., a rising edge of a subsequent clock) with some clock margin, then the data will be accurate when sampled. However, employing the excessive clock margin can affect system performance by introducing excessive time not necessary for providing accurate data.

In contrast to these previous approaches, methods and systems as described herein employ a sensor that can permit determination of voltage-frequency operating combinations that provide sufficient margins based on data propagation times determined using at-speed scans, as described herein. Thus, the approaches herein can ensure that a system is operated at a given voltage-frequency operating combination that provides sufficient clock margin, and yet that also reduces an amount of latency and/or power consumption associated with operation of the system as compared to other approaches such as those that employ an excessive margin.

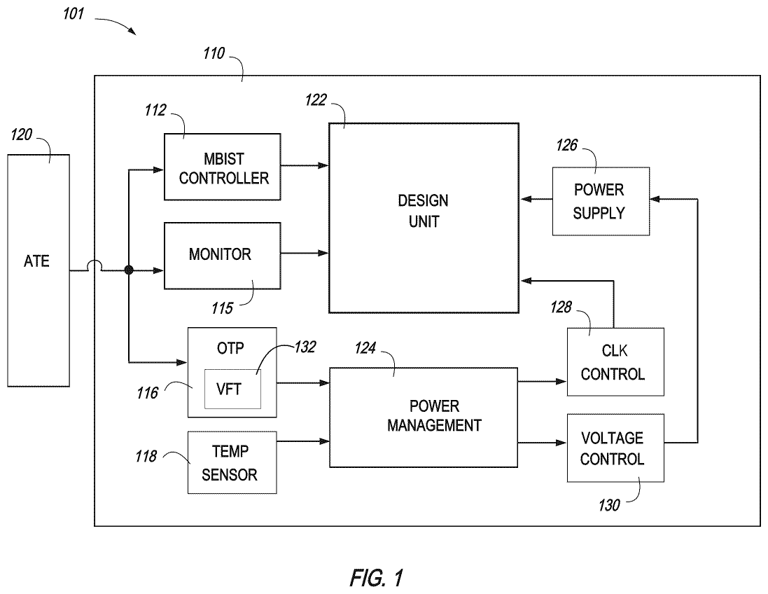

FIG. 1 illustrates an example system 101 for critical timing DVFS based on an at-speed scan in accordance with some embodiments of the present disclosure. The system 101 can include an automatic testing equipment (ATE) component 120 and a system on chip (SoC) 110. A component, such as the ATE component 120 described herein, can include various circuitry to facilitate an operation associated with the component, e.g., testing a portion of an SoC (such as SoC 110). For example, the ATE component 120 can include special purpose circuitry in the form of an ASIC, FPGA, state machine, and/or other logic circuitry or software and/or firmware that can allow the ATE component 120 to test other components and/or parameters of the SoC 110. As an example, the ATE component 120 can be a simple computer-controlled digital multimeter, or a complicated system containing dozens or more complex test instruments (real or simulated electronic test equipment) capable of automatically testing and diagnosing faults in sophisticated electronic packaged parts or on wafer testing, including systems on chips and/or integrated circuits.

Further, the SoC 110 can be an application-specific-integrated circuit (ASIC), a field-programmable gate array (FPGA), etc. The SoC 110 includes a design unit 122 and a power management controller 124. The design unit 122 includes circuitry which can include one or more cores (e.g., “intellectual property (IP) cores”). As used herein, a “core” or “IP core” generally refers to one or more blocks of data and/or logic that form constituent components of an application-specific integrated circuit or field-programmable gate array. The “core(s)” or “IP core(s)” can be designed, built, and/or otherwise configured to perform specific tasks and/or functions within the systems described herein.

The power management controller 124 can be in communication with various components such as the temperature sensor 118 and OTP 116, as described herein. The power management controller can also control aspects of the operation of various components such as the clock control component 128 and the voltage control component 130, as described herein. In some instances, the power management controller 124 can apply or determine whether to perform DVFS operations using the one-time programmable (OTP) memory 116, the temperature sensor 118, and any other available inputs, as will be described below. In some examples, the power management controller 124 can be a power management integrated circuit (or PMIC) used for managing power of the system 101. Although PMIC can refer to a wide range of chips (or modules in system on a chip (SoC) devices), most include several DC/DC converters. A DC-to-DC converter is an electronic circuit or electromechanical device that converts a source of direct current (DC) from one voltage level to another. A PMIC is often included in battery-operated devices such as mobile phones and portable media players to decrease the amount of space required.

The ATE component 120 communicates with the design unit 122 through an MBIST (“memory built-in self-test”) controller 112 and/or a monitor component 115. While an MBIST controller 112 is being described herein, embodiments are not so limited. For example, MBIST is just an example self-test controller/circuit and any number of self-test circuits can be used. The monitor component 115 can refer to circuitry and/or control logic that is used to control and manage monitoring operations (such as an AC scan operation, among other monitoring operations), as will be described further below. MBIST can refer to the industry-standard method of testing embedded memories. MBIST operates by performing sequences of reads and writes according to a test algorithm. Many industry-standard test algorithms exist. An MBIST controller generates the correct sequence of reads and writes to all locations. In doing this, some additional test coverage is achieved in the address and data paths that the MBIST uses. In addition, the design unit 122 can communicate with the power management controller 124 through a clock (“CLK”) control component 128 and a voltage control component 130 that is in communication with a power supply component 126 and communicates through the power supply component 126 to the design unit 122. The voltage control component 130 can control the voltage of the power supply component 126 according to instructions received from the power management controller 124.

The clock control component 128 can include various circuitries and/or logic inserted on the SoC 110 for controlling clocks. The clock control component 128 can scale a clock timing according to instructions received from the power management controller 124. Further, since monitoring of AC (at-speed) testing generally requires two or more clock pulses in capture mode with a frequency equal or substantially close to the functional clock frequency, without the clock control component 128, the at-speed pulses related to the ATE component 120 may need to be provided through the input/output (I/O) pads of the SoC 110. However, these I/O pads can have limitations in terms of the maximum frequency they can support. The clock control component 128, on the other hand, can use, in some examples, an internal phase-lock-loop (PLL) clock for generating clock pulses for test and/or, in other examples, an internal delay-locked-loop (DLL) clock for generating the clock pulses for test. While the clock control component 128 is described as providing clocking for the ATE component 120 and also the clock according to instructions received from the power management controller 124, embodiments are not so limited. For example, the clock control component 128 can be used for scaling the frequency according to instructions from the power management controller 124 to dynamically adjust the frequency for DVF scaling and a different clock control component (not illustrated) can be used solely for the ATE component 120 and for clock timing of the ATE testing itself.

In some examples, the PLL clock can refer to circuitry and/or logic that generates an output signal whose phase is related to the phase of an input signal. Although there are several different types of PLL clock circuits, the simplest is an electronic circuit consisting of a variable frequency oscillator and a phase detector in a feedback loop. The oscillator generates a periodic signal, and the phase detector compares the phase of that signal with the phase of the input periodic signal, adjusting the oscillator to keep the phases matched. Keeping the input and output phase in lock step also implies keeping the input and output frequencies the same. Consequently, in addition to synchronizing signals, a phase-locked loop can track an input frequency, or it can generate a frequency that is a multiple of the input frequency. These properties are used for computer clock synchronization, demodulation, and frequency synthesis.

In the other examples, the delay-locked-loop (DLL) can be a digital circuit similar to a phase-locked loop (PLL), with the main difference being the absence of an internal voltage-controlled oscillator, replaced by a delay line. A DLL can be used to change the phase of a clock signal (a signal with a periodic waveform), usually to enhance the clock rise-to-data output valid timing characteristics of integrated circuits (such as DRAM devices). DLLs can also be used for clock recovery (CDR). From the outside, a DLL can be seen as a negative-delay gate placed in the clock path of a digital circuit. The main component of a DLL can be a delay chain composed of many delay gates connected output-to-input. The input of the chain (and thus of the DLL) is connected to the clock that is to be negatively delayed. A multiplexer can be connected to each stage of the delay chain and the selector of this multiplexer can be automatically updated by a control circuit to produce the negative delay effect. The output of the DLL can be the resulting, negatively delayed clock signal.

Phase-locked loops can be widely employed in radio, telecommunications, computers, and other electronic applications. They can be used to demodulate a signal, recover a signal from a noisy communication channel, generate a stable frequency at multiples of an input frequency (frequency synthesis), or distribute precisely timed clock pulses in digital logic circuits such as microprocessors. Since a single integrated circuit can now provide a complete phase-locked-loop building block, the technique can be widely used in modern electronic devices, with output frequencies from a fraction of a hertz up to many gigahertz. Further, while phase-locked-loops (PLLs) and delay-locked-loops (DLLs) are provided in these examples, embodiments are not so limited. For example, any circuit capable of generating the clock or changes in frequency can be used.

In the instance DC (stuck-at) testing the clock control component 128 can ensure that only one clock pulse is generated in the capture phase. Similarly, during AC (at-speed) testing the clock control component 128 ensures two or more clock pulses are generated in the capture phase, having a frequency equal to the frequency of the functional clock. Therefore, test clocks used in a scan design can be routed through the clock control component 128, which controls the clock operation in the scan mode (both in stuck-at and at-speed testing) and bypasses the functional clock in a functional mode.

Generally, an AC scan is configured to detect an at-speed fault and a DC scan is configured to detect a stuck-on fault. An AC scan detects manufacturing defects that behave as delays on gate input-output ports. So, in an AC scan, each port is tested for logic 0-to-1 transition delay (slow-to-rise fault) or logic 1-to-0 transition delay (slow-to-fall fault). Like stuck-at faults, the at-speed fault can be at the input or output of a gate, thus a simple 2-input AND gate has six possible at-speed faults. As an example, suppose a slow-to-fall fault is occurring at the output of an AND gate. A slower 1-to-0 transition at the output of the AND gate may occur and can affect the value captured. It is important to note that only with an initial state ‘1’ in a flop and 010 at the input will the at-speed fault be able to be detected.

Referring back to the DC (stuck-at) scan, the DC scan models manufacturing defects which occur when a circuit node is shorted to a positive supply voltage or “VDD” (stuck-at-1 fault) or a ground voltage “GND” (stuck-at-0 fault) permanently. The fault can be at the input or output of a gate. Thus, a simple 2-input AND gate has six possible stuck-at faults. As an example, suppose a stuck-at-0 fault is at the output of an AND gate. Note one important thing for this example, there are three input ports in the circuit, thus, there can be a combination of eight different inputs or patterns {000, 001, 010, 011, 100, 101, 110, 111}; out of the eight patterns, only one pattern {011} will be able to detect this fault. As with the rest of the patterns, the expected output can be the same as the actual circuit output in the presence of this stuck-at-0 fault. As this is a small circuit in this example, the pattern can be easily found that detects this fault. However, more complicated circuits will use more complicated stuck-at-0 fault patterns to test all the possible fault locations using complex steps and are contemplated within the scope of the disclosure.

Further, in this example illustrated in FIG. 1, the ATE component 120 can configure the power management controller 124 through a one-time-programmable (“OTP”) memory 116. However, embodiments are not so limited and the power management controller 124 can be configured through other methods or components. For example, a programmable component that is not a one-time programmable component, such as a memory that can be programmed multiple times or more than once, can be used. A one-time-programmable memory (OTP) can refer to a particular type of non-volatile memory (NVM) that permits data to be written to memory only once. Once the memory has been programmed, it retains its value upon loss of power (i.e., is non-volatile). OTP memory can be used in applications where reliable and repeatable reading of data is required. Examples include boot code, encryption keys, and configuration parameters for analog, sensor, or display circuitry. OTP NVM is characterized, over other types of NVM like electronic fuse (eFuse) or electrically-erasable programmable read only memory (EEPROM), by offering a low power, small area footprint memory structure. As such, OTP memory can be used in microprocessors, display drivers, and Power Management ICs (PMICs).

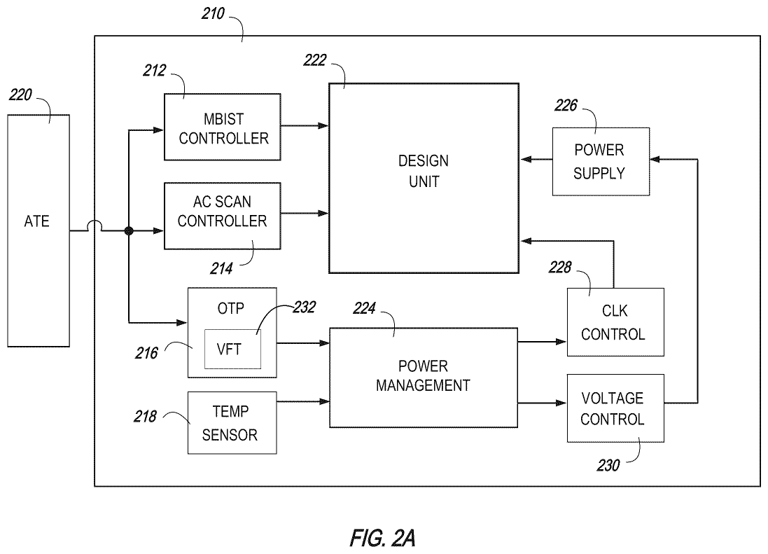

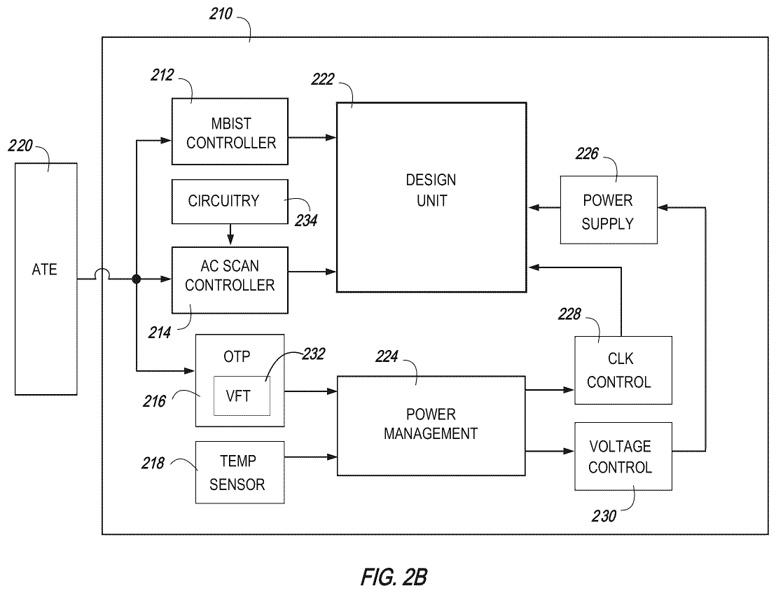

The OTP memory 116 can include a voltage-frequency-temperature table (“VFT”) 132. The VFT table 132 can be a group of cells used to store data related to performance of an AC scan operation and/or data related to performance of a memory built-in self-test (MBIST) operation. As an example, the monitoring operation (e.g., AC scan or other monitoring operations) can be performed by the monitor component 115 (or, in the example of an AC scan, an AC scan controller such as AC scan controller 214 in FIGS. 2A-2B) and the data generated from the monitor operation (e.g., AC scan) and associated with parameters such as voltage (V), frequency (F), temperature (T), etc., and can be stored in the VFT table 132. The stored data in the VFT table 132 can be used to determine a particular frequency and/or voltage (e.g., a voltage-frequency operating combination associated with a particular operating condition such as a operating temperature) to configure the SoC 110, for instance, based on a particular frequency, temperature and/or voltage. While, in some embodiments, a monitor operation can occur at a time of manufacturing and prior to use by a user, a monitor operation can be performed throughout a life cycle of the system 101 and/or SoC 110. For example, at a particular period of time post-manufacturing or post-use by the user, a monitor operation can be performed at boot-up of the SoC 110. The data associated with the frequency and/or voltage and/or temperature and corresponding error rates and/or error quantities may have changed from the initial monitor operation or several initial monitor operations associated with a time of manufacturing. This can be due to effects of age on the cells that can cause the frequency, voltage, and/or temperatures to alter the efficacy and/or accuracy of data stored in the cells over time. Accordingly, adjusted data values based on such post-manufacturing scans can be stored in a register and/or in a particular location within the SoC 110 and can be used to modify how the VFT table 132 is being used to adjust the voltage and/or frequency and/or temperature values of the SoC 110.

Further, a temperature sensor 118 can be in communication with the power management controller 124 and can provide temperature data to the power management controller 124. The temperature sensor 118 can be embedded within the SoC 110 and can provide a temperature value at a number of different locations within the SoC 110. For example, the temperature sensor 118 can be embedded near a power transistor(s) that is near a heat source of the SoC 110. While one temperature sensor 118 is described, embodiments are not so limited. As an example, any number of temperature sensors can be located throughout the SoC 110, such as close to specific heat-dissipating transistors, near the power supply component 126, etc.

In some embodiments, the system 101 can be deployed on, or otherwise included in a system (e.g., a storage device, a memory module, or a hybrid of a storage device and memory module). Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

In other embodiments, the system 101 can be deployed on, or otherwise included in a computing device such as a desktop computer, laptop computer, server, network server, mobile computing device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device. As used herein, the term “mobile computing device” generally refers to a handheld computing device that has a slate or phablet form factor. In general, a slate form factor can include a display screen that is between approximately 3 inches and 5.2 inches (measured diagonally), while a phablet form factor can include a display screen that is between approximately 5.2 inches and 7 inches (measured diagonally). Examples of “mobile computing devices” are not so limited, however, and in some embodiments, a “mobile computing device” can refer to an IoT device, among other types of edge computing devices.

Such computing devices can include a host system that is coupled to a memory system (e.g., one or more storage devices, memory modules, or a hybrid of a storage device and memory module). A host system can include a processor chipset and a software stack executed by the processor chipset. The processor chipset can include one or more cores, one or more caches, a memory controller (e.g., an SSD controller), and a storage protocol controller (e.g., PCIe controller, SATA controller). The host system uses the storage device, the memory module, or a hybrid of the storage device and the memory module, for example, to write data to the storage device, the memory module, or the hybrid of a storage device and memory module and read data from the storage device, the memory module, or the hybrid of a storage device and memory module.

In these examples, the host system can include a processing unit such as a central processing unit (CPU) that is configured to execute an operating system. In some embodiments, the processing unit can execute a complex instruction set computer architecture, such an x86 or other architecture suitable for use as a CPU for a host system.

A host system can be coupled to a memory system via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), or any other interface. The physical host interface can be used to transmit data between the host system and the memory system. The host system can further utilize an NVM Express (NVMe) interface to access components when the memory system is coupled with the host system by the PCIe interface. The physical host interface can provide an interface for passing control, address, data, and other signals between the memory system and the host system. In general, the host system can access multiple memory sub-systems via a same communication connection, multiple separate communication connections, and/or a combination of communication connections.

A system can include any combination of the different types of non-volatile memory devices and/or volatile memory devices. The volatile memory devices can be, but are not limited to, random access memory (RAM), such as dynamic random-access memory (DRAM) and synchronous dynamic random access memory (SDRAM).

Some examples of non-volatile memory devices include negative-and (NAND) type flash memory and write-in-place memory, such as three-dimensional cross-point (“3D cross-point”) memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Although non-volatile memory components such as three-dimensional cross-point arrays of non-volatile memory cells and NAND type memory (e.g., 2D NAND, 3D NAND) are described, the memory device can be based on any other type of non-volatile memory or storage device, such as such as, read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM).

A memory system can also include additional circuitry or components. In some embodiments, a memory system can include a cache or buffer (e.g., DRAM) and address circuitry (e.g., a row decoder and a column decoder) that can receive an address from the memory system controller and decode the address to access the memory device(s).

In some embodiments, memory devices can include local media controllers that operate in conjunction with a memory system controller to execute operations on one or more memory cells of the memory devices. For example, an external controller can externally manage the memory device (e.g., perform media management operations on the memory device). In some embodiments, a memory device is a managed memory device, which is a raw memory device combined with a local controller for media management within the same memory device package. An example of a managed memory device is a managed NAND (MNAND) device.

Although non-limiting examples herein are generally described in terms of applicability to memory systems and/or to memory devices, embodiments are not so limited, and aspects of the present disclosure can be applied as well to a system-on-a-chip, a computing system, data collection and processing, storage, networking, communication, power, artificial intelligence, control, telemetry, sensing and monitoring, digital entertainment and other types of systems and/or devices, Accordingly, aspects of the present disclosure can be applied to these components in order to provide critical timing DVFS based on an at-speed scan, as described herein.

FIG. 2A illustrates an example system for critical timing DVFS based on an at-speed scan in accordance with some embodiments of the present disclosure. Similar to FIG. 1, FIG. 2A can include the same and/or similar components. For example, FIG. 2A illustrates an ATE 220 that is similar to ATE component 120 in FIG. 1 and a system-on-chip (SoC) 210 similar to SoC 110 in FIG. 1. The ATE 220 can communicate with the SoC 210. The SoC 210 can include a design unit 222. The ATE 220 can communicate with the design unit 222. For instance, the ATE 220 can communicate with the design unit 222 through an MBIST controller 212. The ATE 220 can configure the SoC 210. The SoC 210 can include a power management controller 224. The ATE 220 can communicate with the power management controller 224. For instance, the ATE 220 can communicate with the power management controller 224 through an OTP memory 216. The ATE 220 can control the design unit 222 through a clock control component 228, a voltage control component 230 and a power supply 226. A temperature sensor 218 may be in communication with the power management controller 224. However, a distinction from FIG. 1 that is illustrated in FIG. 2A is that instead of the monitor component 115, an AC scan controller 214 is illustrated for more specific performance of AC scan operations, which is a subset of the overall monitoring operations described above.

FIG. 2B illustrates an example system for critical timing DVFS based on an at-speed scan in accordance with some embodiments of the present disclosure. Similar to FIG. 1 and FIG. 2A, FIG. 2B can include the same and/or similar components. For example, FIG. 2B illustrates an ATE 220 that is similar to ATE component 120 in FIG. 1 and a system-on-chip (SoC) 210 similar to SoC 110 in FIG. 1. The SoC 210 can include a design unit 222 that is controlled by the ATE 220 through an MBIST controller 212 and an AC scan controller 214 (similar to FIG. 2A). The SoC 210 can also include a power management controller 224 that is configured by the ATE 220 through an OTP 216 and can control the clock control component 228, a voltage control component 230 and a power supply 226. A temperature sensor 218 may be in communication with the power management controller 224.

However, a distinction from FIG. 1 and FIG. 2A that is illustrated in FIG. 2B is circuitry 234 in communication with the AC scan controller 214. The circuitry 234 can be, for example, circuitry associated with a non-volatile memory device such as, in some examples, a NAND flash memory array. As an additional example, a memory array can be a storage class memory (SCM) array or other such memory arrays, such as, for instance, a three-dimensional cross-point (3D Cross-point) memory array, a ferroelectric RAM (FRAM) array, or a resistance variable memory array such as a PCRAM, RRAM, or spin torque transfer (STT) array, among others. The circuitry 234 can be used to store scan vectors or other testing program data that the AC scan controller 214 can run autonomously without the ATE 220. Further, for example, an AC scan performed during a lifecycle of the SoC 110, 210, as described above, can provide additional voltage, frequency, temperature, and/or error data that can be stored in the circuitry 234. As an example, the OTP 216 may be prevented from being written to (as it is a one-time-programmable memory and may have already been written to initially). In this instance, the stored AC scan data can be accessed from another re-programmable memory in order to modify an analysis of the scan data already stored in the voltage-frequency-temperature (VFT) table 232 in the OTP 216. The VFT table 232 storing the scan data can be adjusted based on the additional scan data stored in the circuitry 234 in order to modify a frequency and/or a voltage and/or temperature and minimize and/or attempt to avoid a number of errors in the SoC 210. In some examples, the OTP 216 may be any other memory, such as reprogrammable memory, etc.

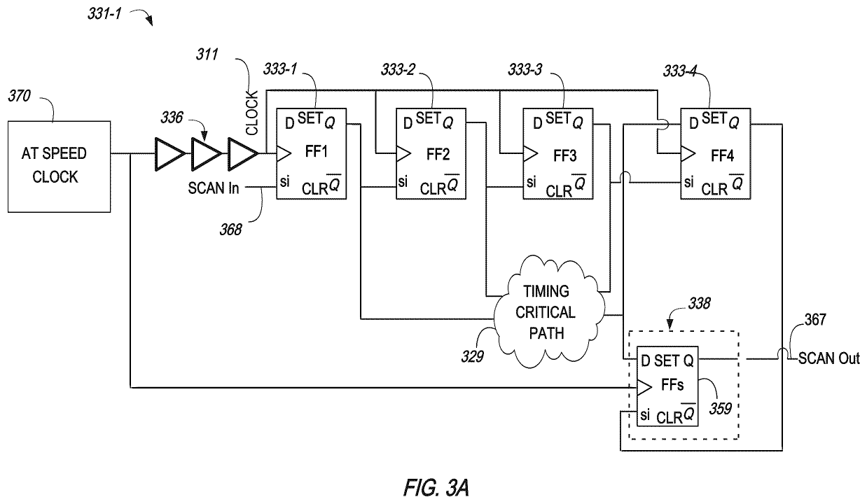

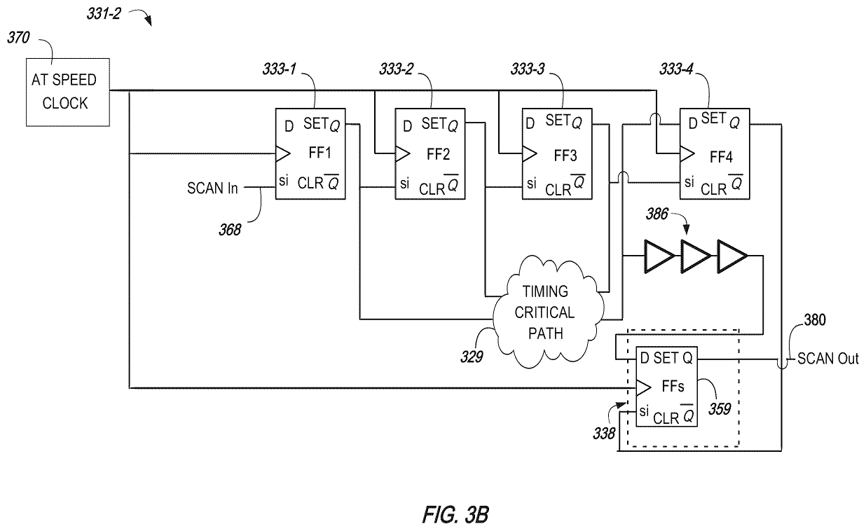

FIG. 3A illustrates an example system 331-1 for critical timing DVFS based on an at-speed scan including a sensor 338 in accordance with some embodiments of the present disclosure. The example system 331-1 employs a sensor 338 set to an earlier clock arrival (e.g., a negative clock offset) that samples data under more stringent conditions than the functional critical endpoint (e.g., the endpoint at flip-flop 333-4). This example helps to protect against a marginal setup violation (e.g., timing violation) in the clocking, e.g., clocking frequency, of the system 331-1.

That is, the system 331-1 can include a power management controller such as those described herein. The power management controller 124 can apply DVFS operations using the one-time programmable (OTP) memory 116, the temperature sensor 118, and any other available inputs, as will be described below. The power management controller can be similar to power management controller 124 in FIG. 1 and/or power management controller 224 in FIGS. 2A-2B. Likewise, the system 331-1 can include a power supply component (not shown), a clock control component 370, a voltage control component (not shown) such as those described herein. A design unit, such as design unit 122 in FIG. 1, can be controlled by the power management controller through the clock (“CLK”) control component and the voltage control component that is in communication with a power supply. The voltage control component can control the voltage of the power supply according to instructions received from the power management controller. In some examples, the power management controller can be a power management integrated circuitry (PMIC).

A signal from the clock control component 370 can be input to a delay line 336. The delay line 336 can include a number of buffers, inverters and/or other cells, illustrated as three buffers in FIG. 3A, however, examples are not so limited. The delay line 336 can be either fixed or configurable. For example, a portion of a clock tree can be the delay line. Configurable or trimmable delay lines can provide better temperature compensation when paired with a temperature sensor, such as temperature sensor 118 and 218 in FIGS. 1-2B, and design unit, such as design unit 122 and 222 in FIGS. 1-2B.

The example system 331-1, which can be referred to in the alternative as an apparatus, includes a plurality of flip-flops 333-1, 333-2, 333-3, 333-4, 359, which are referred to in the alternative as “latches” 333-1, 333-2, 333-3, 333-4, 359 (which are generally referred to as the “the plurality of flip-flops 333 or 359” or “the plurality of latches 333 or 359,” respectively, herein).

As shown in FIG. 3A, the clock control component 370 (e.g., the “AT SPEED CLOCK”) is coupled to the flip-flops 333-1, 333-2, 333-3, 333-4 through the delay line 336. The clock control component can receive a clock signal from circuitry external to the system 331-1. In some embodiments, a clock signal is asserted through the clock control component to initiate the clock gating logic. In general, the “flip-flops” referred to herein are edge-triggered flip-flops (e.g., flip-flops that are edge-triggered devices that respond to a rising or falling edge of a clocking signal) or level-sensitive flip-flops (e.g., flip-flops that are level-triggered devices that are transparent for a particular clock signal level and opaque for a different clock signal level). While FIG. 3A illustrates the plurality of flip-flops 333, examples are not so limited. For example, the example system 331-1 can include, and operate correctly with, any sequential cell-like latch, such as a flip-flop, register, register file, memory, etc.

Each flip-flop in the plurality of flip-flops 333, 359 can be the same type of flip-flop. Having each flip-flop in the plurality of flip-flops 333, 359 be the same type of flip-flop can promote various aspects herein such as permitting accurate and readily determining when a margin is sufficient or insufficient. For instance, each of the flip-flop 333, 359 can be data flip-flops, among other possibilities. Each flip-flop in the plurality of flip-flops 333, 359 can have an edge-triggered clock input (illustrated as a sideways triangle), a data “D” input gate, either or both of a “Q” output, and a Q-bar output. As discussed herein, the first of the flip-flops 333-1 can be clocked by the delay line 336 at the clock input of the first flip-flop 333-1. The flip-flop 333-1, in this case through the “Q” or “Q-bar” output, can be a start point of a critical timing path 329. Likewise, the delay line 336 provides a clock to each of the flip-flops 333-2, 333-3, 333-4. Further, each of the flip-flops 333-2, 333-3, in this case through each of the respective “Q” or “Q-bar” outputs, is a start point of the critical timing path 329. The flip-flop 333-4, through the “D” input, can be an end point of the critical timing path 329.

The sensor 338 includes at least one flip-flop such as flip-flop 359. The flip-flop 359 is part of the sensor 338 that senses the end points of the critical timing path 329. In some embodiments, the sensor 338 includes an individual flip-flop such as the individual flip-flop 359 in the absence of any additional flip-flops, as illustrated in FIGS. 3A-3B. Having the sensor 338 include an individual flip-flop can yield a sensor with fewer components and/or may yield a reduction in computational overhead associated with voltage-frequency scaling to operate a circuit with an optimal margin as compared to other approaches that employ a plurality of flip-flops in a sensor. However, in some embodiments the sensor 338 can include additional components such as a plurality of flip-flops.

The output from the clock control component 370 can be connected to the flip-flop 333-1 and, as mentioned, can also be connected to the delay line 336. The scan input (“SCAN IN”) 368 can be the beginning point or middle point of a scan chain that is provided to a scan input (“si”) of the first flip-flip (FF1) and then is promulgated to respective scan inputs of the other flip-flop 333-2, 333-3, 333-4 and 359. A scan output (“SCAN OUT”) can be the Q output and/or Q bar output of the flip-flop 359 in the sensor 338 and/or can be located along another location of the scan chain.

While illustrated in FIG. 3A and FIG. 3B has each of the flip-flops (e.g., flip-flop 333 and flip-flop 359) on the same scan chain. However, the present disclosure is not so limited. Rather, in some embodiments the flip-flops 333 and the flip-flop 359 can be a separate and distinct chain chains.

The scan output 367 can be an input to scan controller or the ATE which, as described herein, to determine various suitable voltage-frequency operating combinations that provide a sufficient margin. For instance, the scan output can permit determination of whether a first data value (e.g., a data value associated with and a second data value are the same or different data values. Accordingly, a baseline voltage (e.g., minimum voltage) and/or threshold frequency (e.g., maximum clocking frequency) can be determined for a given operating condition such as an operating temperature and subsequently the SoC can be configured to operate at a voltage-frequency operating combination that yields a sufficient timing margin and yet, reduces an operational voltage employed by the SoC and/or maximizes a clocking frequency employed by the SoC to yield improved SoC performance (e.g., reduced power consumption and/or reduced computational overhead, etc.).

FIG. 3B illustrates an example system 331-2 for including a sensor 338 in accordance with some embodiments of the present disclosure. The example system 331-2 is analogous to the system 331-1 but employs a sensor 338 set to an positive data offset that samples data under more stringent conditions (e.g., with shorter time intervals between sampling) than the functional critical endpoint, which is the endpoint represented by the flip-flop 333-4. Thus, unlike FIG. 3A, the delay line 386 can be present prior to the scan input “Si” of the sensor 338. The signals of the sensor 338 can be used by the ATE and/or scan controller, as described herein. For instance, the signals from the sensor 338 can be used to determine a baseline voltage (e.g., minimum voltage) and/or threshold frequency (e.g., maximum clocking frequency) can be determined for a given operating condition such as an operating temperature and subsequently the SoC can be configured (e.g., based on stored values in a data structure such as a table) to operate at a voltage-frequency operating combination that yields a sufficient timing margin and yet, reduce an operational voltage employed by the SoC and/or maximize a clocking frequency employed by the SoC to yield improved SoC performance, as described herein.

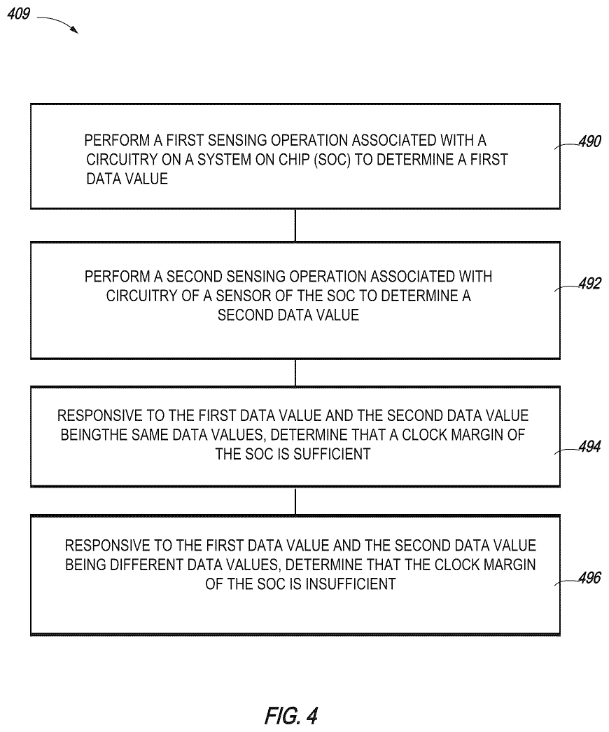

FIG. 4 illustrates an example method 409 in accordance with some embodiments of the present disclosure. The method 409 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At 490, the method 409 can include performing a first sensing operation associated with circuitry (e.g., a flip-flop such as flip-flop 333-4 “FF4”, as illustrated in FIG. 3A and FIG. 3B) on a system on chip (SoC) to determine a first data value associated with the circuitry of the SoC, as described herein. At 492 the method can include performing a second sensing operation associated with circuitry (e.g., a flip-flop such as flip-flop 359 “FFs”, as illustrated in FIG. 3A and FIG. 3B) of a sensor (e.g., which can be located along a scan chain) of the SoC to determine a second data value associated with the circuitry of the sensor, as described herein. As mentioned, the second sensing operation can be performed earlier than the first sensing operation. For instance, the second sensing operations can be associated with the sensor set to an earlier clock arrival in relation to the first sensing operation. However, in some embodiments, the second sensing operation is associated with a sensor set to a later data arrival in relation to the first sensing operation.

In a digital logic circuit, a sensing operation is when a circuit component detects and responds to a particular digital signal on a wire or a specific voltage level on a logic gate input. Sensing can be performed by circuitry including registers, flip-flops, latches, and other types of elements. Sensing operations may be used in digital circuits to control the behavior of the circuit, allowing the circuit to perform specific tasks, such as decision-making, memory storage, and state control. Overall, a sensing operation is an important part of digital logic circuits, allowing circuit components to detect and respond to specific signals, making it possible to perform the desired task. Thus, in some examples described herein, at least one of the plurality of sensing operations (e.g., the second sensing operation) is associated with a sensor set to an earlier clock arrival in relation to at least another of the plurality of sensing operations. In some examples, at least one of the plurality of sensing operations (e.g., the second sensing operation) is associated with a sensor set to a later data arrival in relation to at least another of the plurality of sensing operations. In some examples, the plurality of sensing operations can determine a particular data value stored in a location of data storage elements, e.g., a flip-flop or latch of a system on chip (SoC).

At 494, the method 409 can include determining that a clock margin of the SoC is sufficient, responsive to the first data value and the second data value being the same data values. That is, the SoC may be operating at a voltage-frequency operating combination that provides sufficient margin.

Conversely, at 496, the method 409 can include determining that a clock margin of the SoC is insufficient, responsive to the first data value and the second data value being different data values. That is, the SoC may be operating at a voltage-frequency operating combination that provides insufficient margin (e.g., may lead to data corruption or data loss, etc.).

The method 409 can include storing at least one voltage-frequency operating combination that provides a sufficient margin with a corresponding operating condition such as a particular operating temperature. In some embodiments, the method 409 can include storing only voltage-frequency operating combinations that provide sufficient margins (e.g., not storing any voltage-frequency operating combination associated with a corresponding temperature that provide an insufficient margin). However, in some embodiments, voltage-frequency operating combinations that provide sufficient margin and voltage-frequency operating combination that provides insufficient margins can be stored in a data structure (e.g., a look-up table, etc.) along with corresponding indicators of whether the margin is sufficient or is insufficient. In any case, the SoC can be configured (e.g., based on a given operating condition such as a particular operating temperature) to a particular voltage-frequency operating combination that provides a sufficient margin, as described herein.

The method 409 can include adjusting a voltage and/or a clocking frequency of the SoC responsive to the first data value and the second data value being the same data value. For instance, a voltage can be decreased or a clocking frequency can be increased until additional sampling of data values of the respective circuitry of the sensor and the SoC at the decreased voltage and/or the increased clocking frequency yields sampled data values that are different. Accordingly, the approaches herein can readily determine a base operational voltage (e.g., minimum voltage) of the SoC at a given temperature and/or a threshold operational frequency (e.g., maximum clocking frequency) of the SoC at the given temperature or temperature range. Thus, the approaches herein can permit operation of the SoC at reduced voltages and/or higher (faster) clocking frequency and thereby improve operation of the SoC and yet ensure that the SoC operates with sufficient timing margins (e.g., to mitigate or avoid any data corruption or loss) at a given temperature or temperature range.

As an example, a first sensing operation can be associated with flip-flop of a SoC and a second sensing operation can be associated with a flip-flop of a sensor. In some embodiments, the first sensing operation can occur during a first time window and the second sensing operation can occur during a second time window. The first time window can be the same as the second time window or can be different than the second time window (e.g., the first time window can be offset by a particular amount of clock or data timing from the second time window). For instance, the first time window and the second time window can be the same (e.g., start and stop at the same time) and yet, as described herein, the data values associated with the first sensing operation and the second sensing operation that are sensed at the same time may be the same (e.g., indicating a margin is sufficient) or may different (e.g., indicating the margin is insufficient).

A data value sensed during the first sensing operation can be compared to a data value sensed during the second sensing operation. In response to the comparison, a voltage and/or a clocking frequency of at least one operation of the SoC can be adjusted, thereby adjusting a timing margin of the SoC or taking another remedial action to ensure that the timing margin is sufficient. Examples of remedial actions include adjusting a voltage associated with at least one operation of the SoC, adjusting a frequency of at least one operation of the SoC, logging or otherwise storing a record of the occurrence of the clock margin being insufficient, among other possibilities. For instance, a voltage and/or a frequency of the at least one operation of the SoC can be adjusted to minimize power consumption (e.g., reduce an operational voltage of a SoC) and/or reduce latency (e.g., increase an operational frequency of the SoC), and yet ensure that a timing margin is sufficient. Thus, the timing margin can be adjusted such that a setup time and/or a hold time is adjusted such that a sampled data value is accurate or correct and the setup time and/or hold time is sufficient. For instance, in some embodiments sampled data values of a fourth flip in the SoC and flip-flop in the sensor may be employed to determine whether or not the margin is sufficient, as described herein. For instance, the SoC can be configured to operate a particular voltage-frequency operating combination that ensure sufficient margin, for instance, depending on an operational temperature, etc. For instance, the voltage can be incrementally reduced and/or the frequency can be incrementally increased until the sensors described herein detect an insufficient margin (e.g., a setup violation correspond to an incorrect (different) data value being sample at the sensor FF 359). That is, due to the FF 359 being configured with earlier clocking and/or later a data arrival time the FF may have a different data value (e.g., as compared to FF 333-4) and thereby permit determination of a base operational voltage (minimal voltage) of the SoC and/or a threshold operational frequency (maximum frequency) of the SoC that still yield sufficient clocking margin for operation of the SoC. When operating with a sufficient margin the data values at the FF 359 and the FF 333-4 are the same due to the presence of a sufficient margin for both the FF 359 and the FF 333-4. Stated differently, when operating with a sufficient margin there is an absence of a setup violation at both the FF 359 and the FF 333-4.

TABLE 1

| 1^{st} voltage- | 2^{nd} | 3^{rd} | Operating | |
|---|---|---|---|---|
| frequency operating | voltage- | voltage- | temperature | |
| combination | frequency | frequency | (Degrees | |
| (Volts (V), | operating | operating | Celsius | |
| Megahertz (MHz)) | combination | combination | (C. °) | |
| 0.70 V-500 MHz | 0.72 V-530 MHz | 0.74 V-550 MHz | 25° | C. ° |
| 0.70 V-520 MHz | 0.72 V-545 MHz | 0.74 V-570 MHz | 50 | C. ° |

Thus, embodiments herein yield at least one voltage-frequency operation combination that is stored in a data structure and yield sufficient margin for a given operating condition such as a given operating temperature. For instance, as illustrated in Table 1, a plurality of voltage-frequency operating combinations (e.g., having different respective frequencies and/or voltages) may be determined as described herein and may be stored in the data structure. For example, a voltage-frequency operating combination associated with at least one operation of the SoC may be stored in a data structure such as the data structure represented by Table 1.

Having a plurality of voltage-frequency operating combinations stored and permit operation of the SoC at a variety of potential voltage-frequency operating combinations for a given temperature. For instance, a stored voltage-frequency operating combination that provides a clock margin of the SoC that is sufficient can selected based on a particular operating condition such as a given operating temperature of the SoC that corresponds to the stored voltage-frequency operating combination.

Thus, such approaches may permit added flexibility on how the SoC is configured to operate at a given operating condition such as a given operating temperature (e.g., 25 C°, 50 C°, etc.) and thereby yield further improvements in the operation of the SoC depending for instance on a computational load, type of data, and/or particular application associated with operation of the SoC. Accordingly, the approaches herein can readily determine a base operational voltage (minimal voltage) of the SoC and/or a threshold operational frequency (maximum frequency) of the SoC that still yield sufficient clocking margin for operation of the SoC. In some embodiments, the base operational voltage of the SoC is substantially equal to a last voltage at which the data values of the first sensing operation and the second sensing operation are the same value. In some embodiments, a threshold operational frequency of the SoC is substantially equal to a highest frequency at which the data values of a sensing operation associated with the flip-flop of the SoC and the flip-flop of the sensor are same data value. As used herein, the term “substantially” intends that the characteristic need not be absolute, but is close enough so as to achieve the advantages of the characteristic. For example, “substantially equal” is not limited to an absolute value, but can include similar values such as those within 10 percent, 5 percent, or 1 percent of a given value. Thus, the approaches herein can permit operation of the SoC at reduced voltages such as a base operational voltage and/or higher (faster) clocking frequency such as a threshold operational frequency and thereby improve operation of the SoC and yet ensure that the SoC operates with sufficient timing margins (e.g., to mitigate or avoid any data corruption or loss).

While Table 1 illustrates a total of three different voltage-frequency operating combinations for a given temperature the disclosure is not so limited and can include additional or fewer voltage-frequency operating combinations for a given temperature. While Table 1 illustrates different voltage-frequency operating combinations associated with an individual temperature values (e.g., 25) C°, the present disclosure is not so limited and can include additional temperature values and/or temperature ranges associated with different voltage-frequency operating combinations.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including solid state drives (SSDs), hard disk drives (HDDs), floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A method comprising:
performing a first sensing operation associated with a circuitry on a system on chip (SoC) to determine a first data value associated with the circuitry of the SoC;
performing a second sensing operation associated with circuitry of a sensor to determine a second data value associated with the circuitry of the sensor;
responsive to the first data value and the second data value being the same data values, determining that a clock margin of the SoC is sufficient; and
responsive to the first data value and the second data value being different data values, determine that the clock margin of the SoC is insufficient.

2. The method of claim 1, further comprising storing, in a data structure, a voltage-frequency operating combination associated with at least one operation of the SoC during the first sensing operation, the second sensing operation, or both.

3. The method of claim 1, further comprising configuring the SoC to operate at a stored voltage-frequency operating combination that provides a clock margin of the SoC that is sufficient.

4. The method of claim 3, wherein the stored voltage-frequency operating combination that provides the clock margin of the SoC that is sufficient is selected based on a particular operating condition of the SoC that corresponds to the stored voltage-frequency operating combination.

5. The method of claim 1, wherein the second sensing operation is associated with the sensor set to an earlier clock arrival in relation to the first sensing operation.

6. The method of claim 5, wherein the earlier clock arrival is imparted by a delay line that is coupled to the circuitry of the SoC.

7. The method of claim 1, wherein the second sensing operation is associated with a sensor set to a later data arrival in relation to the first sensing operation.

8. The method of claim 7, wherein the later data arrival is imparted by a delay line that is coupled to at least the circuitry of the sensor.

9. An apparatus, comprising:
a controller configured to:
perform a first sensing operation associated with circuitry on a system on chip (SoC) to determine a first data value associated with the circuitry of the SoC;
perform a second sensing operation associated with circuitry of a sensor to determine a second data value associated with the circuitry of the sensor at the second time window;
responsive to the first data value and the second data value being the same data value, determine that a clock margin of the SoC is sufficient;
responsive to the first data value and the second data value being different data values, determine that the clock margin of the SoC is insufficient; and
storing, in a data structure, a voltage-frequency operating combination associated with at least one operation of the SoC.

10. The apparatus of claim 9, wherein:
the circuitry in the SoC is a first flip-flop; and
the circuitry in the sensor is a second flip-flip.

11. The apparatus of claim 10, wherein the circuitry in the sensor comprises an individual flip-flop.

12. The apparatus of claim 11, wherein the sensor comprises the individual flip-flop in the absence of an additional flip-flop.

13. The apparatus of claim 11, further comprising a delay line, wherein the delay line is coupled to the circuitry in the SoC or individual flip-flop.

14. The apparatus of claim 10, wherein the controller is configured to:
incrementally decrease a voltage associated with the SoC until the first sensing operation and the second sensing operation have different data value to determine a base operational voltage of the SoC; or
incrementally increase a voltage associated with the SoC until the first sensing operation and the second sensing operation have the same data value to determine the base operational voltage of the SoC.

15. The apparatus of claim 14, wherein the base operational voltage of the SoC is substantially equal to a last voltage at which the data values of the first sensing operation and the second sensing operation are the same value.

16. The apparatus of claim 10, wherein the controller is configured to incrementally increase a frequency associated with the SoC until the first sensing operation and the second sensing operation have different data values to determine a threshold operational frequency of the SoC.

17. The apparatus of claim 16, wherein the threshold operational frequency of the SoC is substantially equal to a last voltage at which the data values of the first sensing operation and the second sensing operation and the same value.

18. An apparatus, comprising:
a voltage control component;
a clock control component; and
a controller coupled to the voltage control component and the clock control component, wherein the controller is configured to:
perform a first sensing operation associated with a flip-flop on a system on chip (SoC) to determine a first data value associated with the flip-flop of the SoC;
perform a second sensing operation associated with an individual flip-flop of a sensor of the SoC to determine a second data value associated with the individual flip-flop of the sensor;
responsive to the first data value and the second data value being the same data value:
incrementally alter a voltage, incrementally alter a clocking frequency, or both, associated with at least one operation of the SoC;
perform an additional sensing operations to determine:
a subsequent data value associated with the flip-flop on the SoC; and
a subsequent data value associated with the individual flip-flop of the sensor;
store at least one voltage-frequency operating combinations of the SoC associated with the first data value, the second data value, and the subsequent data values, in a data structure; and
configure the SoC to operate at one of the stored voltage-frequency operating combinations which provides a sufficient margin.

19. The apparatus of claim 18, wherein the controller is configured to incrementally decrease a voltage associated with the SoC until the first sensing operation and the second sensing operation have different data value to determine a base operational voltage of the SoC, wherein the base operational voltage of the SoC is substantially equal to a lowest voltage at which the data values of sensing operations associated with the flip-flop of the SoC and the flip-flop of the sensor are same data value.

20. The apparatus of claim 18, wherein the controller is configured to incrementally increase a frequency associated with at least one operation of the SoC to determine a threshold operational frequency of the SoC, wherein the threshold operational frequency of the SoC is substantially equal to a highest frequency at which the data values of a sensing operation associated with the flip-flop of the SoC and the flip-flop of the sensor are same data value.
